(19) United States
(12) Patent Application Publication
(10) Pub. No.: US 2015/0279659 A1
(43) Pub. Date: Oct. 1, 2015

(54) VAPOR PHASE GROWTH APPARATUS AND VAPOR PHASE GROWTH METHOD

(71) Applicant: NuFlare Technology, Inc., Kanagawa (JP)

(72) Inventors: Hideshi TAKAHASHI, Kanagawa (JP); Yuusuke SATO, Tokyo (JP)

(21) Appl. No.: 14/670,728

(22) Filed: Mar. 27, 2015

(30) Foreign Application Priority Data
Mar. 31, 2014 (JP) 2014-073344

(51) Int. Cl. H01L 21/02; H01L 21/67; C23C 16/448; C23C 16/455; C23C 16/06; C23C 16/44

(52) U.S. Cl. CPC H01L 21/0262; C23C 16/06; C23C 16/4412; C23C 16/4482; C23C 16/455; H01L 21/67248

(57) ABSTRACT

A vapor phase growth apparatus according to embodiments includes: a reaction chamber; a first reservoir container storing a first organic metal; a source gas supply passage receiving a main carrier gas and supplying a source gas containing the first organic metal to the reaction chamber; a thermostatic room containing the first reservoir container and configured to have an internal temperature set higher than an external temperature thereof; a first carrier gas supply passage supplying a first carrier gas to the first reservoir container; a first organic metal-containing gas transfer passage connected outside the thermostatic room to the source gas supply passage to transfer a first organic metal-containing gas containing the first organic metal generated by bubbling or sublimation in the first reservoir container; and a dilution gas transfer passage connected inside the thermostatic room to the first organic metal-containing gas transfer passage transferring a dilution gas.

### CROSS-REFERENCE TO RELATED APPLICATION

This application is based upon and claims the benefit of priority from Japanese Patent Applications No. 2014-073344, filed on Mar. 31, 2014, the entire contents of which are incorporated herein by reference.

### FIELD

The present disclosure relates to apparatuses and methods for vapor phase growth by which film formation is performed with gas supply.

### BACKGROUND

Methods for forming high-quality semiconductor films include epitaxial growth technology of growing a single-crystal film by vapor phase growth on a substrate such as a wafer. In a vapor phase growth apparatus for use in epitaxial growth technology, a wafer is placed on a support in a reaction chamber that is maintained at an atmospheric pressure or in reduced pressure. Then, a process gas such as a source gas to be a material of the film to be formed is supplied onto the surface of the wafer from, for example, a shower plate disposed in an upper portion of the reaction chamber while the wafer is being heated. A reaction such as thermal reaction of the source gas occurs on the surface of the wafer, such that an epitaxial single-crystal film is formed on the surface of the wafer.

Recently, GaN (gallium nitride) semiconductor devices are drawing attention as a material for light emitting devices or power devices. The epitaxial growth technology for forming GaN semiconductor films includes the metalorganic chemical vapor deposition method (MOCVD method). By the metalorganic chemical vapor deposition method, for example, an organic metal such as trimethylgallium (TMG), trimethylindium (TMI), and trimethylaluminum (TMA) , and ammonia (NH₃) are used as a source gas.

According to the MOCVD method, a liquid or solid organic metal stored in a reservoir is bubbled or sublimed with a gas such as hydrogen to generate a source gas containing the organic metal, such that the gas is supplied to the reaction chamber. Since, however, the saturated vapor pressures of organic metals are relatively low, stable supply of an organic metal-containing gas is difficult to achieve (JP-A H07-307291.)

### SUMMARY

A vapor phase growth apparatus according to one embodiment of the present invention includes: a reaction chamber; a first reservoir container storing first organic metal; a source gas supply passage receiving a main carrier gas, the source gas supply passage supplying a source gas containing the first organic metal to the reaction chamber; a thermostatic room containing the first reservoir container, the thermostatic room being configured to have an internal temperature to be set higher than an external temperature of the thermostatic room; a first carrier gas supply passage supplying a first carrier gas to the first reservoir container; a first organic metal-containing gas transfer passage connected to the source gas supply passage, the first organic metal-containing gas transfer passage and the source gas supply passage being connected at a first junction provided outside of the thermostatic room, the first organic metal-containing gas transfer passage transferring a first organic metal-containing gas generated by bubbling or sublimation in the first reservoir container, the first organic metal-containing gas containing the first organic metal; and a dilution gas transfer passage connected inside the thermostatic room to the first organic metal-containing gas transfer passage, the dilution gas transfer passage transferring a dilution gas.

A vapor phase growth method according to one embodiment of the present invention includes: transferring a substrate into a reaction chamber; performing bubbling or sublimation on a first organic metal by using a first carrier gas in a temperature environment at a predetermined temperature; keeping a first organic metal-containing gas in a temperature environment at or above the predetermined temperature until dilution is performed with a dilution gas, the first organic metal-containing gas being generated by the bubbling or sublimation and containing the first organic metal; diluting the first organic metal-containing gas with the dilution gas in a temperature environment at or above the predetermined temperature; mixing the first organic metal-containing gas diluted with the dilution gas with a main carrier gas in a temperature environment below the predetermined temperature to generate a source gas; and supplying the source gas to the reaction chamber to form a semiconductor film on a surface of the substrate.

### BRIEF DESCRIPTION OF THE DRAWINGS

FIG. 1 is a configuration diagram of a vapor phase growth apparatus according to an embodiment.

FIG. 2 is a schematic cross-sectional view of principal parts of the vapor phase growth apparatus according to an embodiment.

### DETAILED DESCRIPTION

Embodiments of the present invention are described below with reference to the drawings.

It is to be noted herein that the direction of gravity in a state where a vapor phase growth apparatus is set for film formation is defined as “down,” and the direction opposite thereto is defined as “up.” Hence, a “lower portion” means a position in the direction of gravity with respect to a reference, and a “downward/below” means the direction of gravity with respect to the reference. An “upper portion” means a position in the direction opposite the direction of gravity with respect to the reference, and “upward/above” means the direction opposite the direction of gravity with respect to the reference. The “vertical direction” is the direction of gravity.

Further, the “process gas” herein is a generic term for gases for use in forming a film on a substrate and is a concept encompassing, for example, a source gas, a carrier gas, a dilution gas, a separation gas, a compensation gas, and a bubbling gas.

Further, the “compensation gas” herein is a process gas that does not contain a source gas. The compensation gas is supplied to the reaction chamber, prior to the supply of the source gas to the reaction chamber, through the same supply passage as that for the source gas. Switching is performed from the compensation gas to the source gas immediately before film formation, such that an environmental change, such as a change in internal pressure and temperature of the reaction chamber, is suppressed to a maximum extent, so as to stably perform film formation on the substrate.

Further, the “separation gas” herein is a process gas to be introduced into the reaction chamber of the vapor phase growth apparatus and is a generic term for gases for separating a plurality of process gases for material gases.

A vapor phase growth apparatus according to an embodiment includes: a reaction chamber; a first reservoir container configured to store a first organic metal; a source gas supply passage configured to receive a main carrier gas and to supply a source gas containing the first organic metal to the reaction chamber; a thermostatic room containing the first reservoir container, the thermostatic room being configured to have an internal temperature to be set higher than an external temperature of the thermostatic room; a first carrier gas supply passage configured to supply a first carrier gas to the first reservoir container; a first organic metal-containing gas transfer passage connected outside the thermostatic room to the source gas supply passage, the first organic metal-containing gas transfer passage being configured to transfer a first organic metal-containing gas to be generated by bubbling or sublimation in the first reservoir container, the first organic metal-containing gas containing the first organic metal; and a dilution gas transfer passage connected inside the thermostatic room to the first organic metal-containing gas transfer passage, the dilution gas transfer passage being configured to transfer a dilution gas.

Further, a vapor phase growth method according to an embodiment includes: transferring a substrate into a reaction chamber; performing bubbling or sublimation by using a carrier gas in a temperature environment at a predetermined temperature; keeping a first organic metal-containing gas in a temperature environment at or above the predetermined temperature until dilution is performed with a dilution gas, the first organic metal-containing gas being generated by the bubbling or sublimation and containing the first organic metal; mixing the first organic metal-containing gas diluted with the dilution gas with a main carrier gas in a temperature environment below the predetermined temperature to generate a source gas; and supplying the source gas to the reaction chamber to form a semiconductor film on a surface of the substrate.

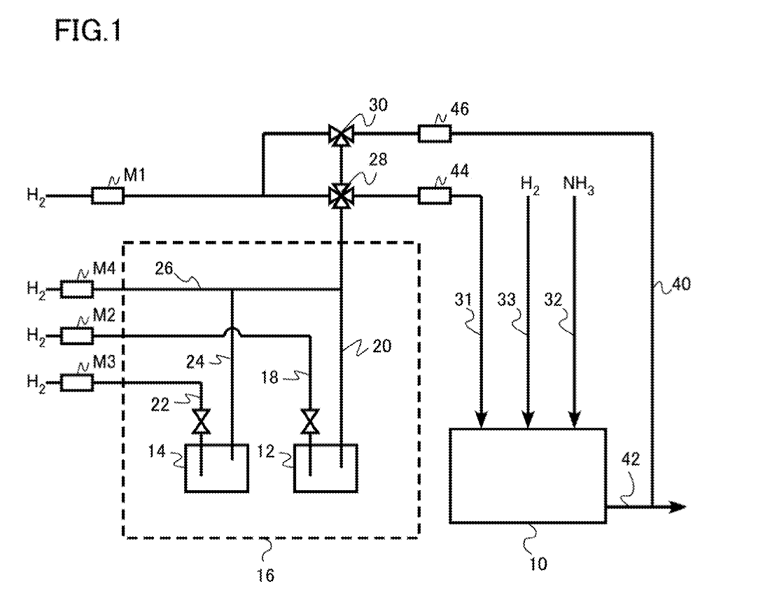

FIG. 1 is a configuration diagram of a vapor phase growth apparatus according to the present embodiment. The vapor phase growth apparatus according to the present embodiment is a vertical, single wafer type epitaxial growth apparatus adopting the MOCVD method (metalorganic chemical vapor deposition method.) Description is given below mainly of a case which GaN (gallium nitride) is epitaxially grown.

The vapor phase growth apparatus includes a reaction chamber 10. A film formed on a substrate such as a wafer in the reaction chamber 10. The vapor phase growth apparatus includes a first gas supply passage (a source gas supply passage) 31, a second gas supply passage 32, and a third gas supply passage 33. These gas supply passages are configured to supply process gases to the reaction chamber 10.

A main carrier gas is supplied to the first gas supply passage 31. The first gas supply passage 31 includes a mass flow controller M1 for controlling the flow rate of the main carrier gas.

The first gas supply passage 31 supplies to the reaction chamber a first process gas (a source gas) containing an organic metal of a group III element and the main carrier gas. The first process gas contains a group III element for forming a group III-V semiconductor film on a wafer. The main carrier gas is, for example, hydrogen gas.

The group element is, for example, gallium (Ga), aluminum (Al) , or indium (In). The organic metal is, for example, trimethylgallium (TMG) trimethylaluminum (TMA) , or trimethylindium (TMI).

Further, the vapor phase growth apparatus includes a first reservoir container 12 and a second reservoir container 14. The first reservoir container 12 stores a first organic metal. The second reservoir container 14 stores a second organic metal. The second organic metal is different from the first organic metal. The first organic metal reservoir container 12 stores, for example, liquid TMG to be a source of gallium. The second organic metal reservoir container 14 stores solid Cp₂Mg (bis (cyclopentadienyl)magnesium) to be a source of magnesium (Mg). Magnesium is going to be a p-type dopant for gallium.

It is to be noted that the number of reservoir containers is not limited to two and may be one or not less than three. Further, the organic metals to be stored in the first reservoir container 12 and the second reservoir container 14 are not limited to TMG and Cp₂Mg and may be other organic metals such as TMA and TMI.

The vapor phase growth apparatus includes a thermostatic room 16 that contains the first reservoir container 12 and the second reservoir container 14. The internal temperature of the thermostatic room 16 is higher than the external temperature of the thermostatic room. The internal temperature of the thermostatic room 16 is desirably not lower than 30° C. from the viewpoint of keeping the vapor pressure of the first organic metal high. Further, the internal temperature of the thermostatic room 16 is set below the boiling point of the first organic metal from the viewpoint of retaining the first organic metal in a liquid state or solid state. Moreover, the internal temperature of the thermostatic room 16 is desirably not higher than 60° C. from the viewpoint of controlling the temperature of the thermostatic room.

Further, the vapor phase growth apparatus includes a first carrier gas supply passage 18 for supplying a first carrier gas to the first reservoir container 12. The first carrier gas supply passage 18 includes a mass flow controller M2 for controlling the flow rate of the first carrier gas. The first carrier gas is, for example, hydrogen gas.

A first organic metal-containing gas transfer passage 20 is disposed in connection with the first reservoir container 12. The first organic metal-containing gas transfer passage 20 is configured to transfer a first organic metal-containing gas to be generated with the first carrier gas. The first organic metal-containing gas contains the first organic metal.

Further, the vapor phase growth apparatus includes a second carrier gas supply passage 22 for supplying a second carrier gas to the second reservoir container 14. The second carrier gas supply passage 22 includes a mass flow controller M3 for controlling the flow rate of the second carrier gas. The second carrier gas is, for example, hydrogen gas.

A second organic metal-containing gas transfer passage 24 is disposed in connection with the second reservoir container 14. The second organic metal-containing gas transfer passage 24 is configured to transfer a second organic metal-containing gas to be generated with the second carrier gas. The second organic metal-containing gas contains the second organic metal.

The vapor phase growth apparatus includes a dilution gas transfer passage 26 for transferring a dilution gas. The dilution gas transfer passage 26 is connected inside the thermostatic room 16 to the first organic metal-containing gas transfer passage 20 and the second organic metal-containing gas transfer passage 24. The dilution gas transfer passage 26 includes a mass flow controller M4 for controlling the flow rate of the dilution gas. The dilution gas is, for example, hydrogen gas.

The first organic metal-containing gas to be transferred by the first organic metal-containing gas transfer passage 20 is diluted with the dilution gas inside the thermostatic room 16. Further, the second organic metal-containing gas to be transferred by the second organic metal-containing gas transfer passage 24 is diluted with the dilution gas inside the thermostatic room 16.

The first organic metal-containing gas transfer passage 20 and the second organic metal-containing gas transfer passage 24 are connected to the first gas supply passage (the source gas supply passage) 31 at a first joint 28. The first joint 28 is, for example, a four-way valve and is configured to control between inflow and shutoff of the organic metal with respect to the first gas supply passage 31. When the four-way valve is open, the organic metal is supplied to the first gas supply passage 31. When the four-way valve is closed, the organic metal is not supplied to the first gas supply passage 31.

Further, the vapor phase growth apparatus includes a gas exhaust passage 40. The gas exhaust passage 40 is disposed so as to discharge the gas containing the first organic metal or the second organic metal out of the apparatus detouring the reaction chamber 10 when the vapor phase growth apparatus is not in a film forming state.

The gas exhaust passage 40 branchesfrom the first gas supply passage (the source gas supply passage) 31. The gas exhaust passage 40 is supplied with the main carrier gas.

The gas exhaust passage 40 is connected outside the thermostatic room 16 to the first organic metal-containing gas transfer passage 20 and the second organic metal-containing gas transfer passage 24 at a second joint 30. The second joint 30 is, for example, a three-way valve and is configured to control between inflow and shutoff of the organic metals with respect to the gas exhaust passage 40. When the three-way valve is open, organic metals are supplied to the gas exhaust passage 40. When the three-way valve is closed, the organic metals are not supplied to the gas exhaust passage 40. The gas exhaust passage 40 is connected to a path 42 for discharging gases from the reaction chamber 10.

A first regulator 44 is positioned on the reaction chamber 10 side of the first gas supply passage 31 with respect to the first joint 28. In other words, the first regulator 44 is positioned on the reaction chamber 10 side of the first gas supply passage 31 with respect to the junction between the first organic metal-containing gas transfer passage 20 and the second organic metal-containing gas transfer passage 24.

Further, a second regulator 46 is positioned on the gas exhaust passage 40 on the outer side of the vapor phase growth apparatus with respect to the second joint 30. In other words, the second regulator 46 is positioned in the gas exhaust passage 40 on the outer side of the vapor phase growth apparatus with respect to the junction between the first organic metal-containing gas transfer passage 20 and the second organic metal-containing gas transfer passage 24.

The first regulator 44 is a back pressure regulator, and the second regulator 46 is a mass flow controller. The back pressure regulator has a function of maintaining the pressure on the primary side, i.e., the upstream side of the back pressure regulator, to a constant value.

The second gas supply passage 32 is configured to supply a second process gas containing ammonia (NH₃) to the reaction chamber. The second process gas is a source gas of a group V element and nitrogen (N) for forming a group III-V semiconductor film on a wafer. The second gas supply passage 32 is supplied with the second process gas. The second gas supply passage 32 includes a mass flow controller (not shown) for controlling the flow rate of the second process gas to be supplied to the second gas supply passage 32.

Further, the third gas supply passage 33 is disposed to supply a third process gas to the reaction chamber 10. The third process gas is a so-called separation gas and is jetted between the first process gas and the second process gas when the first process gas and the second process gas are jetted into the reaction chamber 10. This suppresses reaction between the first process gas and the second process gas immediately after the gases are jetted.

A mass flow controller (not shown) for controlling the flow rate of the separation gas to be supplied to the third gas supply passage 33 is positioned in the third gas supply passage 33. The separation gas is, for example, hydrogen gas.

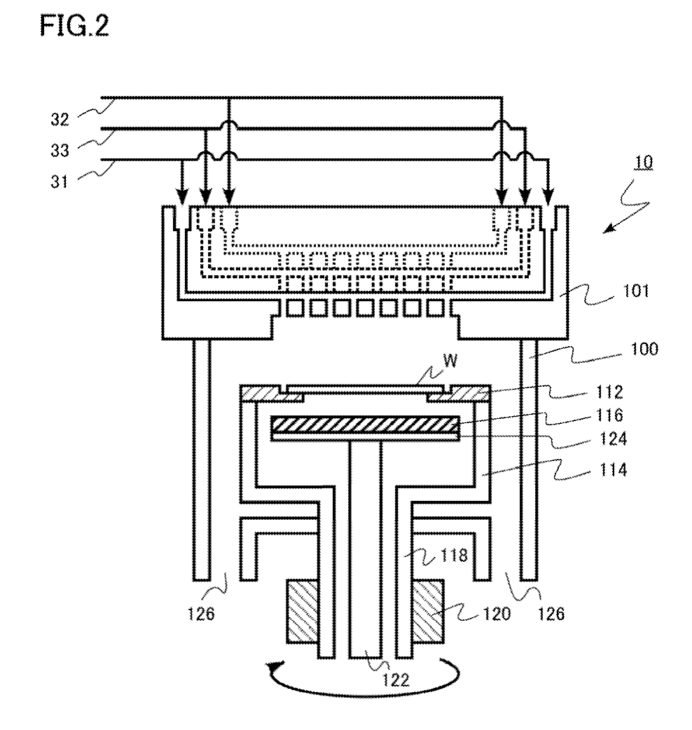

FIG. 2 is a schematic cross-sectional view of principal parts of the vapor phase growth apparatus according to the present embodiment. As depicted in FIG. 2, the reaction chamber 10 according to the present embodiment includes, for example, a wall portion 100 made of stainless steel in the form of a cylindrical hollow body. The vapor phase growth apparatus includes a shower plate 101 for supplying a process gas into the reaction chamber 10. The shower plate 101 is positioned in an upper portion of the reaction chamber 10.

Further, the vapor phase growth apparatus includes a support 112 on which a semiconductor wafer is substrate) W is placeable. The support 112 is positioned below the shower plate 101 inside the reaction chamber 10. The support 112 is, for example, a ring holder with an opening at a central portion thereof, or a susceptor having a structure to contact almost the entire rear surface of the semiconductor wafer W.

The three gas passages, i.e., the first gas supply passage 31, the second gas supply passage 32, and the third gas supply passage 33, are connected to the shower plate 101. A plurality of gas spouts is arranged in the shower plate 101 on the reaction chamber 10 side so as to jet out into the reaction chamber 10 the first, second, and third process gases to be supplied through the first gas supply passage 31, the second gas supply passage 32, and the third gas supply passage 33.

Further, a heater serving as a heating portion 116 is positioned below the support 112 so as to heat the wafer W placed on a rotor unit 114 and the support 112. The rotor unit 114 is rotatable with the support 112 mounted thereon. The rotor unit 114 has a rotation shaft 118 thereof connected to a rotary drive mechanism 120 that is positioned in a lower portion. The rotary drive mechanism 120 allows the semiconductor wafer W to be rotated at a rate of, for example, 50 rpm to 3000 rpm with respect to the center of the rotary drive mechanism 120.

The cylindrical rotor unit 114 desirably has a diameter that is approximately equal to the outer diameter of the support 112. It is to be noted that the rotation shaft 118 is rotatably positioned on a bottom portion of the reaction chamber 10 with a vacuum seal member interposed therebetween.

The heating portion 116 is fixedly positioned on a support mount 124 that is fixedly attached to a support shaft 122. The support shaft 122 penetrates the inner portion of the rotation shaft 118. The heating portion 116 is supplied with power by a current inlet terminal and an electrode that are not shown. The support mount 124 is provided with, for example, a push up pin (not shown) for removing the semiconductor wafer W from the ring holder 112.

Moreover, a gas outlet 126 is provided in a bottom portion of the reaction chamber 10 so as to discharge a reaction product and a residual process gas in the reaction chamber 10 out of the reaction chamber 10. The reaction product and residual process gas are generated following the reaction of the source gas on, for example, the surface of the semiconductor wafer W. The gas outlet 126 is connected to the gas exhaust passage 40 (FIG. 1) by way of the gas exhaust path 42.

It is to be noted that the reaction chamber 10 depicted in FIG. 2 has a wafer gateway and a gate valve that are not shown at positions on a sidewall of the reaction chamber 10 so as to load and unload a semiconductor wafer W. It is configured such that a semiconductor wafer W is transferred by a handling arm between, for example, a load lock chamber (not shown) and the reaction chamber 10 that are coupled by the gate valve. It is to be noted here that the handling arm made of, for example, synthetic quartz is insertable into a space between the shower plate 101 and the wafer support 112.

A vapor phase growth method according to the present embodiment is performed by using the epitaxial growth apparatus of FIGS. 1 and 2. Description is given below as regards the vapor phase growth method according to the present embodiment of an exemplary case in which p-type GaN with magnesium used as a p-type dopant is epitaxially grown.

First, a semiconductor wafer W serving as an example of the substrate is loaded into the reaction chamber 10.

In case where, for example, a p-type GaN film is formed on the semiconductor wafer W, for example, TMG and Cp₂Mg with hydrogen gas used as the main carrier gas are supplied through the first gas supply passage 31. Further, for example, ammonia is supplied through the second gas supply passage 32. Further, for example, hydrogen gas serving as the separation gas is supplied through the third gas supply passage 33.

TMG serving as one example of the first organic metal is stored in the first reservoir container 12. Cp₂Mg serving as one example of the second organic metal is stored in the second reservoir container 14. Then, the internal temperature of the thermostatic room 16 containing the first reservoir container 12 and the second reservoir container 14 is set higher than the external temperature of the thermostatic room 16. For example, the temperature is set not lower than 30° C. and also below the boiling points of TMG and Cp₂Mg.

For example, hydrogen gas is supplied as the first carrier gas through the first carrier gas supply passage 18 to TMG in a liquid state stored in the first reservoir container 12, so as to cause bubbling. A gas containing gallium (the first organic metal-containing gas) is generated as a result of this bubbling.

Further, for example, hydrogen gas is supplied as the second carrier gas through the second carrier gas supply passage 22 to Cp₂Mg in a solid state stored in the second reservoir container 14, so as to sublime Cp₂Mg into the hydrogen gas. A gas containing magnesium (the second organic metal-containing gas) is generated as a result of this sublimation of Cp₂Mg into the hydrogen gas.

Since the temperature of the thermostatic room 16 is set to a predetermined temperature that is not lower than 30° C. and also below the boiling points of TMG and Cp₂Mg, the temperatures of TMG and Cp₂Mg are also maintained at the predetermined temperature. Thus, the bubbling or sublimation of TMG and Cp₂Mg is performed in the temperature environment at this predetermined temperature.

Next, until the gas containing gallium (the first organic metal-containing gas) and the gas containing magnesium (the second organic metal-containing gas) to be generated as a result of the bubbling or sublimation are diluted with a dilution gas, the temperature environment is maintained not lower than the predetermined temperature, and the dilution with the dilution gas is performed at a temperature not lower than the predetermined temperature.

In this example, the gas containing gallium and the gas containing magnesium are diluted inside the thermostatic room 16 with hydrogen gas serving as one example of the dilution gas to be supplied through the dilution gas transfer passage 26. Since the temperature of the thermostatic room 16 is set at a predetermined temperature that is not lower than 30° C. and also below the boiling points of TMG and Cp₂Mg, the gas containing gallium and the gas containing magnesium are kept in a temperature environment at the predetermined temperature and are diluted at the predetermined temperature.

Next, the gas containing gallium and the gas containing magnesium that have been diluted with hydrogen gas are mixed with the main carrier gas in a temperature environment below the predetermined temperature, so as to generate a source gas. In this example, hydrogen gas serving as one example of the main carrier gas to be supplied to the first gas supply passage 31 is mixed outside the thermostatic room 16 with the gas containing gallium as well as the gas containing magnesium and the main carrier gas.

The internal temperature of the thermostatic room 16 is set such that the external temperature of the thermostatic room 16 is lower than the internal temperature of the thermostatic room 16. Thus, the gas containing gallium and the gas containing magnesium are mixed with hydrogen gas serving as the main carrier gas in a temperature environment below the predetermined temperature, and a source gas is generated. The source gas containing TMG and Cp₂Mg is generated with hydrogen gas used as the main carrier gas by the method described above, which source gas is to be supplied through the first gas supply passage 31 into the reaction chamber 10.

Description is given below of a specific process inside a reaction chamber with the reaction chamber 10 adopted as an example.

Hydrogen gas is supplied through, for example, the three gas supply passages 31, 32, and 33 to the reaction chamber 10. A vacuum pump (not shown) is actuated to exhaust the gas in the reaction chamber 10 from the gas outlet 126. A semiconductor wafer W is placed on the support 112 in the reaction chamber 10 in a state where the reaction chamber 10 is controlled at a predetermined pressure.

For loading the semiconductor wafer W, for example, the gate valve (not shown) at the wafer gateway of the reaction chamber 10 is opened, and the semiconductor wafer W in the load lock chamber is transferred into the reaction chamber 10 by the handling arm. Then, the semiconductor wafer W is placed on the support 112 with, for example, the push up pin (not shown) interposed therebetween, the handling arm is returned to the load lock chamber, and the gate valve is closed.

At this point, the semiconductor wafer W placed on the support 112 is preliminarily heated to a predetermined temperature by the heating portion 116. After that, the heating power of the heating portion 116 is raised, so as to raise the temperature of the semiconductor wafer W to a predetermined temperature for baking, for example, on the order of 1150° C.

Then, exhaust by the vacuum pump is continued, and baking prior to film forming is performed at the same time, with the rotor unit 114 being rotated at a predetermined rate. For example, a native oxide on the semiconductor wafer W is removed by this baking.

In baking, hydrogen gas is supplied through the gas supply passages 31, 32, and 33 into the reaction chamber 10.

The baking is performed for a predetermined period of time, and then, for example, the heating power of the heating portion 116 is lowered to lower the temperature of the semiconductor wafer W to a temperature for epitaxial growth of, for example, 1100° C.

TMG and Cp₂Mg (the first process gas: source gas) with hydrogen gas used as the main carrier gas are supplied from the first gas supply passage 31 through the shower plate 101 into the reaction chamber 10. Further, ammonia (the second process gas) is supplied from the second as supply passage 32 through the shower plate 101 into the reaction chamber 10. Further, hydrogen gas (the third process gas) is supplied as the separation gas from the third gas supply passage 33 through the shower plate 101 into the reaction chamber 10. This causes a p-type GaN film to be epitaxially grown on the surface of the semiconductor wafer W.

On completion of epitaxial growth, a group III source gas is stopped from flowing into the first gas supply passage 31. This completes the growth of the GaN single-crystal film. The heating power of the heating portion 116 is lowered to lower the temperature of the semiconductor wafer W, such that the temperature of the semiconductor wafer W is lowered to a predetermined temperature. After that, ammonia is stopped from being supplied through the second gas supply passage 32 to the reaction chamber 10.

On completion of film formation, hydrogen gas is supplied to the reaction chamber 10 through the first gas supply passage 31. Further, hydrogen gas is supplied to the reaction chamber 10 through the second gas supply passage 32.

At this point, for example, the rotor unit 114 is stopped from rotation, and the semiconductor wafer W having a single-crystal film formed thereon is left on the support 112, when the heating power of the heating portion 116 is returned to the initial level, so as to adjust the temperature to be lowered to the temperature for preliminary heating.

Next, the semiconductor wafer W is detached from the support 112 by, for example, the push up pin. Then, the gate valve is opened again to insert the handling arm into the space between the shower plate 101 and the support 112, and the semiconductor wafer W is placed thereon. Then, the handling arm with the semiconductor wafer W placed thereon is returned to the load lock chamber.

As described above, one time of film formation on the semiconductor wafer W is completed. For example, subsequent another film formation may be performed on the semiconductor wafer W according to the same process sequence as described. above.

The vapor phase growth apparatus according to the present embodiment is configured such that the internal temperature of the thermostatic room 16 is set higher than the environmental temperature outside the thermostatic room 16. The internal temperature of the thermostatic room 16 is set at a higher temperature, such that the saturated vapor pressures of the organic metals in the gases are made higher, and the concentration of the organic metals contained in the gases is made higher even at the same flow rate of the carrier gas. Thus, a large amount of organic metal-containing gas is stably suppliable with a simple and convenient configuration.

Further, the saturated vapor pressures of the organic metals are increased, which allows for reduction in flow rate for supplying carrier gas for evaporating the organic metals of the same amounts into the gases. Thus, running costs of the apparatus is reduced. Further, the gas flow rates and the concentration of the organic metals in the oases are prevented from becoming unstable due to a pressure loss in the pipes.

In addition, the vapor phase growth apparatus according to the present embodiment is operable to retain the temperatures of gases containing organic metals to or above a temperature for bubbling or sublimation of the organic metals until the gases are diluted with dilution gas. Thus, the temperatures of the gases containing the organic metals are prevented from lowering before dilution, which otherwise causes a fall in saturated vapor pressure of the organic metals and condensation of the organic metals.

The vapor phase growth apparatus according to the present embodiment is configured such that further dilution of the organic metal-containing gases with the main carrier gas is performed in the outside of the thermostatic room 16 that is at a lower temperature than the thermostatic room 16. Since dilution of the organic metals is already performed once in a high temperature environment, condensation of the organic metals is less likely to occur even though the organic metal-containing gases are transferred to the outside, which is at a lower temperature, of the thermostatic room 16.

The vapor phase growth apparatus according to the present embodiment is configured to perform initial dilution inside the thermostatic room 16. Thus, flow rate controlling instruments including valves and mass flow controllers and pressure controlling instruments that are arranged in flow passages leading to the reaction chamber 10 are positioned outside the thermostatic room 16. Hence, the thermostatic room 16 is downsized, and the design of the apparatus is simplified. Accordingly, downsizing of the apparatus, reduction in manufacturing cost, and reduction in running cost are achieved.

Further, according to the vapor phase growth method according to the present embodiment, higher concentration of organic metal-containing gas and stabilization of the concentration are achieved. Thus, a large amount of organic metal-containing gas is stably supplied. Further, reduction in running cost is achieved by reduction flow rate for supplying carrier gas.

Embodiments of the present invention are described above with reference to specific examples. The above embodiments are described by way of examples and are not intended to restrict the present invention. Further, components of the embodiments may be appropriately combined.

For example, while description is given in the embodiments of an exemplary case in which a single-crystal film of a p-type GaN (gallium nitride) is formed, the present disclosure is applicable to formation of other group III-V nitride semiconductor single-crystal films, for example, of n-type GaN, nondoped GaN, AlN (aluminum nitride) AlGaN (aluminumgallium nitride), and InGaN (indiumgallium nitride.) Further, the present disclosure is applicable to a group III-V semiconductor such as GaAs.

Further, while description is given of an example in which the main carrier gas, carrier gas, dilution gas, and separation gas are hydrogen gas (H₂) , other gases such as nitride gas (N₂) , argon gas (Ar) , and helium gas (He) , or a combination of these gases are adoptable.

Further, while description is given in the embodiments of a vertical, single wafer type epitaxial apparatus configured to form a film per wafer, the vapor phase growth apparatus is not limited to single wafer type epitaxial apparatuses. For example, the present disclosure is applicable to a chemical vapor deposition (CVD) apparatus of the planetary method that is configured to perform film formation on a plurality of revolving/rotating wafers, or to a horizontal epitaxial apparatus.

In the embodiments, description is not given for parts and portions which are not directly relevant to the description of the present disclosure, such as the configuration of the apparatus or the manufacturing method; however, a configuration of an apparatus or a manufacturing method may be appropriately selected for use as needed. In addition, the scope of the present disclosure encompasses any apparatus and method for vapor phase growth that include elements of the present disclosure and that is of an appropriate design choice for those skilled in the art. The scope of the present disclosure is defined by the appended claims and equivalents thereof.

What is claimed is:

1. A vapor phase growth apparatus, comprising:
a reaction chamber;
a first reservoir container storing a first organic metal;
a source gas supply passage receiving a main carrier gas, the source gas supply passage supplying a source gas containing the first organic metal to the reaction chamber;
a thermostatic room containing the first reservoir container, the thermostatic room being configured to have an internal temperature to be set higher than an external temperature of the thermostatic room;
a first carrier gas supply passage supplying a first carrier gas to the first reservoir container;
a first organic metal-containing gas transfer passage connected to the source gas supply passage, the first organic metal-containing gas transfer passage and the source gas supply passage being connected at a first junction provided outside of the thermostatic room, the first organic metal-containing gas transfer passage transferring a first organic metal-containing gas generated by bubbling or sublimation in the first reservoir container, the first organic metal-containing gas containing the first organic metal; and
a dilution gas transfer passage connected. inside the thermostatic room to the first organic metal-containing gas transfer passage, the dilution gas transfer passage transferring a dilution gas.

2. The vapor phase growth apparatus according to claim 1, further comprising a gas exhaust passage connected to the first organic metal-containing gas transfer passage, the gas exhaust passage and the first organic metal-containing gas transfer passage being connected at a second junction provided outside of the thermostatic room, the gas exhaust passage receiving the main carrier gas, the gas exhaust passage exhausting the first organic metal-containing gas out of the vapor phase growth apparatus in such a manner as to detour the reaction chamber.

3. The vapor phase growth apparatus according to claim 2, further comprising:
a first regulator positioned in the source gas supply passage on a side of the reaction chamber with respect to the first junction; and
a second regulator positioned in the gas exhaust passage on an outer side of the vapor phase growth apparatus with respect to the second junction, wherein
the first regulator is a back pressure regulator, and the second regulator is a mass flow controller.

4. The vapor phase growth apparatus according to claim 1, further comprising:
a second reservoir container contained in the thermostatic room, the second reservoir container storing a second organic metal different from the first organic metal;
a second carrier gas supply passage supplying a second carrier gas to the second reservoir container; and
a second organic metal-containing gas transfer passage connected to the source gas supply passage at the first junction, the second organic metal-containing gas transfer passage transferring a second organic metal-containing gas generated by bubbling or sublimation in the second reservoir container, the second organic metal-containing gas containing the second organic metal, wherein
the dilution gas transfer passage is connected inside the thermostatic room to the second organic metal-containing gas transfer passage.

5. The vapor phase growth apparatus according to claim 1, wherein the internal temperature of the thermostatic room is adapted to be lower than a boiling point of the first organic metal.

6. The vapor phase growth apparatus according to claim 1, wherein the internal temperature of the thermostatic room is a temperature in a range from 30° C. to 60° C.

7. The vapor phase growth apparatus according to claim 1, wherein the main carrier gas and the first carrier gas are hydrogen gas.

8. The vapor phase growth apparatus according to claim 1, wherein the dilution gas is hydrogen gas.

9. The vapor phase growth apparatus according to claim 1, wherein the first organic metal is any of trimethylgallium (TMG), trimethylaluminum (TMA), trimethylindium (TMI), or Cp₂Mg (bis(cyclopentadienyl)magnesium).

10. The vapor phase growth apparatus according to claim 4, wherein the second organic metal is any of trimethylgallium (TMG) trimethylaluminum (TMA) trimethylindium (TMI) , or Cp₂Mg (bis(cyclopentadienyl)magnesium).

11. A vapor phase growth method, comprising:
loading a substrate into a reaction chamber;
performing bubbling or sublimation on a first organic metal by using a first carrier gas in a temperature environment at a predetermined temperature;
keeping a first organic metal-containing gas in a temperature environment at or above the predetermined temperature until dilution is performed with a dilution gas, the first organic metal-containing gas being generated by the bubbling or sublimation and containing the first organic metal;
diluting the first organic metal-containing gas with the dilution gas in a temperature environment at or above the predetermined temperature;
mixing the first organic metal-containing gas diluted with the dilution gas with a main carrier gas in a temperature environment below the predetermined temperature to generate a source gas; and
supplying the source gas to the reaction chamber to form a semiconductor film on a surface of the substrate.

12. The vapor phase growth method according to claim further comprising:
performing bubbling or sublimation on a second organic metal by using a second carrier gas in a temperature environment at the predetermined temperature, the second organic metal being different from the first organic metal;
keeping a second organic metal-containing gas in a temperature environment at or above the predetermined temperature until dilution is performed with the dilution gas, the second organic metal-containing gas being generated by the bubbling or sublimation and containing the second organic metal; and
diluting the second organic metal-containing gas with the dilution gas in a temperature environment at or above the predetermined temperature, wherein
the first organic metal-containing gas diluted with the dilution gas and the second organic metal-containing gas diluted with the dilution gas are mixed with the main carrier gas in a temperature environment below the predetermined. temperature to generate the source gas.

13. The vapor phase growth method according to claim 11, wherein the predetermined temperature is below a boiling point of the first organic metal.

14. The vapor phase growth method according to claim 11, wherein the predetermined temperature is a temperature in a range from 30° C. to 60° C.

15. The vapor phase growth method according to claim 11, wherein the main carrier gas and the first carrier gas are hydrogen gas.

16. The vapor phase growth method according to claim 11, wherein the dilution gas is hydrogen gas.

17. The vapor phase growth method according to claim 11, wherein the first organic metal is any of trimethylgallium (TMG) trimethylaluminum (TMA) trimethylindium (TMI), or Cp₂Mg (bis(cyclopentadienyl)magnesium).

18. The vapor phase growth method according to claim 12, wherein the second organic metal is any of trimethylgallium (TMG) trimethylaluminum (TMA) trimethylindium (TMI) , or Cp₂Mg (bis(cyclopentadienyl)magnesium).
